(19) United States
(12) Patent Application Publication
(10) Pub. No.: US 2011/0220382 A1
(43) Pub. Date: Sep. 15, 2011

(54) METHOD FOR PRODUCING A LAYER SYSTEM ON A SUBSTRATE AND LAYER SYSTEM

(75) Inventors: Jurgen Pistner, Alzenau-Michelbach (DE); Torsten Schmauder, Egelsbach (DE); Stephan Kuper, Bad Homburg v. d. H. (DE)

(73) Assignee: LEYBOLD OPTICS GMBH, Alzenau (DE)

(21) Appl. No.: 13/055,748

(22) PCT Filed: Jul. 23, 2009
(86) PCT No.: PCT/EP09/05368

§ 371 Date: Jun. 1, 2011

(30) Foreign Application Priority Data
Jul. 25, 2008 (DE) 10 2008 034 991.7

(51) Int. Cl. H05K 5/00; H05K 1/00; H05K 1/09; B05D 1/36; C23C 16/44; C23C 16/50; B05D 5/00; B05D 5/06; C23C 14/34; C23C 14/06

(52) U.S. Cl. 174/50; 174/250; 174/257; 427/404; 427/250; 427/576; 204/192.1

(57) ABSTRACT

In the method for producing a layer system on a dielectric substrate in which a metal layer is applied onto the substrate by a coating step (110) and a further layer with a predetermined layer thickness is subsequently applied by a further coating step (140), the metal layer having a sheet resistance >10 Mohm and an average reflectance >50%, the further layer would have a sheet resistance <1 Mohm if it had been applied onto the substrate with the same layer thickness by the further coating step (140), and the layer system consisting of the metal layer and the further layer has a sheet resistance >10 Mohm, where the invention furthermore relates to a layer system on a dielectric substrate in which a metal layer is applied onto the substrate by a coating step (110) and a further layer with a predetermined layer thickness is subsequently applied by a further coating step (140), the metal layer having a sheet resistance >10 Mohm and an average reflectance >50%, where the further layer, if it had been applied onto the substrate with the same layer thickness by the further coating step (140), would have a sheet resistance <1 Mohm, and the layer system consisting of the metal layer and the further layer has a sheet resistance >10 Mohm, the invention further providing a housing including a layer system.

### TECHNICAL FIELD

The present invention relates to a method for producing a layer system on a substrate, and to a layer system on a substrate, respectively corresponding to the precharacterizing clauses of the independent patent claims. The invention furthermore relates to a housing, comprising such a layer system, for an electrical device.

### BACKGROUND

The metallization of dielectric substrates, for example by means of vacuum metallization, has already been known for some time. For example, thermal evaporation or sputtering may be used as vacuum metallization methods.

At least since the U.S. Pat. No. 4,431,711, it has furthermore been known that metals, for example indium (In) or tin (Sn), can initially grow by island growth during vacuum metallization. Thin layers of these metals then consist of islands which are not in electrical contact with one another. These layers already have optical properties of the metal—for example metallic sheen—but are not conductive and can therefore be resistant to electrochemical corrosion mechanisms.

Electrically nonconductive vacuum metallized layers (NCVM layers) are intended below to mean layers which consist of metals or metal alloys, which are produced by a vacuum coating method and preferably exhibit no significant reflection in the frequency range of between about 400 MHz and about 5 GHz.

Some years ago, a new application field for NCVM layers opened up: housings for e.g. mobile devices with wireless communication functions, for example mobile telephones, electronic organizers, GPS navigation devices, radar distance sensors. These housings are intended, on the one hand, to have metal-like optics and, on the other hand, to constitute a virtually interference-free environment for the antennas fitted inside. Electrically conductive metal layers would at least partially reflect the radio waves in the conventionally used frequency range of about 400 MHz to about 5 GHz, and thus lead to undesired transmission and reception losses. Such housings are therefore provided with NCVM layers instead of conductive metal layers.

Since the radiofrequency properties of NCVM layers can only be checked by elaborate measurement methods, the DC sheet resistance which can still be measured by simple measuring devices (for example handheld multimeters) is often considered as a criterion, for example a value of 20 Mohm/□ or 1 Gohm/□. The sheet resistance ρ□ of a layer having a thickness d is defined in the case of an isotropic resistivity ρ according to:

ρ□=ρ/d.

The sheet resistance of a layer can be measured by means of the four-point method or the van der Pauw method. In what follows, the sheet resistance will be given in simplified notation in units of ohms.

Colored layer systems for metallic reflectors can be produced in various ways:
reflector with a partially absorbing high refractive index layer, which contains for instance nitrides, carbonitrides, oxides and substoichiometric variants thereof
reflector with a dielectric layer and semitransparent reflection layers.

Conventionally, such layer systems are electrically conductive.

Colored interference layer systems are furthermore known, consisting of a sequence of high and low refractive index dielectric layers. A disadvantage with these layer systems is that the resulting color impression is very sensitively dependent on layer thickness variations.

The document JP 05 065 650 A discloses the production of a dielectric layer with embedded metal particles, although it has the disadvantage of complicated process configuration.

Coatings which appear metallic, including colored ones, can also be applied by lacquer systems. This has some disadvantages. For example, high yield losses of up to 60% due to lacquering defects are often reported. Furthermore, a plurality of lacquer layers are usually necessary (colored lacquer, clear hard lacquer), which entails extra costs.

### BRIEF SUMMARY

The invention provides electrically nonconductive layer systems having a metallic appearance and transparency in the radiofrequency range.

In the method according to the invention for producing a layer system on a dielectric substrate, a metal layer is applied onto the substrate by a coating step and a further layer with a predetermined layer thickness is subsequently applied by a further coating step, the metal layer having a sheet resistance >10 Mohm and an average reflectance >50%. The further layer, if it was applied onto the substrate with the same layer thickness by the further coating step, would have a sheet resistance <1 Mohm, and the layer system comprising the metal layer and the further layer has a sheet resistance >10 Mohm.

In the present text, a dielectric substrate refers to a substrate comprising a dielectric material, in which case the substrate may also comprise a dielectric sublayer onto which the metal layer is applied by the coating step. A metal layer refers to a layer in which the material of the layer comprises a metal or alloys. The first and/or second coating steps may respectively comprise substeps.

According to the invention, electrically nonconductive layer systems, which have for example color effects, can be produced by applying the further layers. Furthermore, the further layers may provide mechanical protection or be used to set particular properties of the surface, without the layer system losing the radiofrequency transparency. The invention is based on the discovery that an electrically nonconductive metal layer has a structure comprising metal islands. According to the invention, such a layer as the base layer of a layer system is subjected to further coating, in which case the steep edges of the islands at least partially shadow the regions between the islands from the coating flow. Consequently, the subsequently applied layer likewise has an island structure and is also electrically nonconductive and radiofrequency (RF) transparent at least in a range of from 400 MHz to 5 GHz.

It is to be understood that a plurality of further layers may also be applied according to the invention onto the metal layer, the layer system comprising the metal layer and the further layers having a sheet resistance >10 Mohm. These further layers, if respectively applied onto the substrate with the same layer thickness by a corresponding coating step, would have a sheet resistance <1 Mohm.

The metal layer is advantageously an NCVM layer, i.e. it is applied by a vacuum method. The metal layer may be applied by a PVD method (for example evaporation, sputtering or a combination of the two) or by a PECVD method. The further layer is preferably also applied by a vacuum method, in particular a reactive PVD or PECVD method. An advantage of using vacuum methods is that it is possible to avoid the yield losses which would occur with the colored lacquering used in the prior art.

With the method, layer systems with different thickness can advantageously be produced in a straightforward way. The total thickness of the layer system comprising the metal layer and the further layer, for example in the case of a TiₓN_{y} layer on a tin layer, preferably lies between 100 nm and 400 nm. The thickness of the metal layer may in this case lie in a range of between 30 nm and 100 nm, in particular 50 nm. The further layer preferably has a thickness of >20 nm and <300 nm.

With the method according to the invention, it is possible to produce a layer system which advantageously has a different color impression than the substrate.

The L*a*b* color system may in this case be used for characterization of the color impression. The standard system of the L*a*b* color system developed by the CIE commission for psychophysical color stimulus specification (Commission International de l'Eclairage, CIE publication No. 15.2, Colorimetry, 2nd., Central Bureau of the CIE, Vienna 1986) is described, for example, in the ASTM designation 308-01 (Standard Practice for Computing the Colors of Objects by Using the CIE System, November 2001) and is based on the properties of human perception.

According to the invention, there is preferably a color distance ΔE*=[(L*ₗ−L*)²+(a*ₗ−a*)²+(b*ₗ−b*)²]^{1/2}>2.0 between the color impression of the substrate with the layer system applied and the color impression of the substrate without the layer system, the color impression of the layer system being C_{layer}=(L*ₗ, a*ₗ, b*ₗ) and the color impression of the substrate being C=(L*, a*, b*). L* is a measure of the lightness, a* of the red-green value and b* of the yellow-blue value of the color impression. The color impression may in this case vary as a function of the layer thickness of the further layer.

The layer system according to the invention, is applied on a dielectric substrate and has a metal layer applied on the substrate by a coating step and a further layer with a predetermined layer thickness subsequently applied by a further coating step, the metal layer having a sheet resistance >10 Mohm and an average reflectance >50%. The layer system is distinguished in that the further layer, if it had been applied onto the substrate with the same layer thickness by the further coating step, would have a sheet resistance <1 Mohm, and in that the layer system comprising the metal layer and the further layer has a sheet resistance >10 Mohm.

By the combination of the nonconductive metal layer and the further nonconductive layer, the layer system can have new, hitherto unachievable, in particular colored design effects. An improved photostability can furthermore be achieved, since there are no organic dyes which can be affected by UV breakdown.

The metal layer is preferably an NCVM layer. The further layer is preferably also applied by a vacuum method.

The metal layer may be produced from at least one element of the group tin, indium, lead, bismuth, gallium, aluminum, cerium, chromium or iridium, or from an alloy of at least two elements of the group tin, indium, lead, bismuth, gallium, aluminum, cerium, chromium or iridium, so that layers having different properties adapted to different application fields can advantageously be achieved.

The resistivity of the bulk material of the further layer is <1 Mohm·cm, although the layer system has a sheet resistance >10 Mohm.

Oxides, nitrides, oxynitrides, carbides, carbonitrides or borides of suitable metals are preferred materials for the further layer, since colored layers can be produced relatively simply with these.

The further layer may advantageously be applied by reactive sputtering of at least one element of the group titanium, zirconium, cerium, aluminum, iridium, chromium, silicon, niobium or tantalum with a reactive gas which comprises at least one element of the group nitrogen, carbon, oxygen, boron.

If the average reflectance of the layer system, preferably in the frequency range of between 400 MHz and 5 GHz, differs by <25% from a corresponding average reflectance of the substrate without the layer system, a layer system which reflects relatively little is obtained.

There is advantageously a color distance ΔE*=[(L*ₗ−L*)²+(a*ₗ−a*)²+(b*ₗ−b*)²]^{1/2}>2.0 between the color impression of the substrate with the layer system applied and the color impression of the substrate without the layer system. Here, the color impression of the layer system is C_{layer}=(L*ₗ, a*ₗ, b*ₗ) and the color impression of the substrate is C=(L*, a*, b*).

The invention can be used to produce a layer system for colored reflector layers: a layer of reactively sputtered TiₓN_{y} (with 1<x<1.5 and 0.5<y<2) is applied onto a base reflector having a substrate and a discontinuous metal layer. Optical properties (refractive index and absorption) are set according to the specific stoichiometry of the TiₓN_{y} layer, and together with the layer thickness of the TiₓN_{y} layer and the optical properties of the underlying metal layer these determine the reflection color of the layer system. The layer system may have a metallic appearance, since sufficient light is reflected even though the metal layer is very thin.

Further advantages of the layer system correspond to the advantages of the method according to the invention which have already been explained.

The housing according to the invention, has a housing body which is used as a dielectric substrate and which comprises a dielectric material, preferably polycarbonate, and a layer system according to the invention applied on the substrate.

Owing to the high sheet resistance, the housing is transmissive for radiofrequency radiation between 400 MHz and 5 GHz, but it nevertheless has a metallic or colored appearance. The housing is furthermore lightweight if the substrate material is plastic, for example polycarbonate.

### BRIEF DESCRIPTION OF THE DRAWINGS

Further aspects, advantages and features of the method according to the invention and of the layer system may be found in the following embodiments and the figures of the drawing, in which:

FIG. 1 shows a schematic representation of an exemplary layer system

FIG. 2 shows a graphical representation of the colors which can be set by the layer thickness of the TiₓN_{y} layer, in a projection of the L*a*b* color space onto the a*-b* plane

FIG. 3 shows a flow chart of a typical method according to the invention.

### DETAILED DESCRIPTION

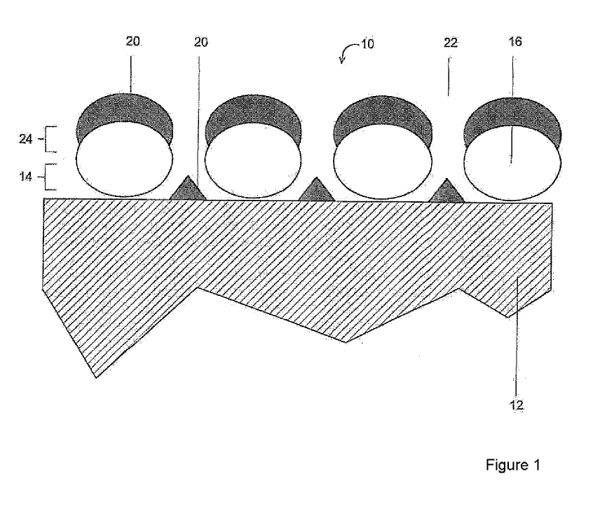

FIG. 1 schematically represents a layer system which is applied on a dielectric substrate 12. The substrate 12 is preferably produced from a dielectric material, in particular plastic. The substrate 12 particularly preferably consists of polycarbonate. The substrate 12 may be a housing body, for example for a mobile telephone, a laptop or another electrical or electronic device, or part of a housing. Of course, the housing may also be provided for a static device.

The layer 14 applied directly on the substrate 12 comprises islands 16, which contain a metal element or a metal alloy. The islands 16 form a discontinuous metal layer on the substrate 12. Valleys 22 are formed between the islands 16. The metal layer has a sheet resistance >10 Mohm.

A further layer 24 is applied, preferably also by means of a vacuum process, onto the metal layer 14 described above. The further layer 24 likewise comprises islands 20, so that a discontinuous layer is also formed by the further layer 24. There are therefore no uninterrupted paths for electrical conduction processes. The further layer 24 is therefore likewise electrically nonconductive and transparent for radiofrequency radiation in the range of from 400 MHz to 5 GHz. The average reflectance is preferably more than 50%.

The further layer 24 would have a sheet resistivity <1 Mohm if it had been applied onto a substrate 14.

The bulk resistivity of the material of the further layer 24 is less than 1 Mohm. The further layer 24 is produced from a metal or a metal alloy and a reactive gas. A typical material used is titanium, with nitrogen being employed as the reactive gas and a preferably substoichiometric titanium nitride layer being formed. It is, however, also possible to use other materials which can form oxides, nitrides or oxynitrides, carbides or borides.

The layer system comprising the metal layer 14 and the further layer 24 is preferably protected by a clear scratch-resistant lacquer. This is not represented in FIG. 1.

The substrate 12 with the layer system 10 applied and the substrate 12 without the layer system may have a color distance ΔE*=[(Lₗ−L*)²+(a*ₗ−a*)²+(bₗ−b*)²]^{1/2} which is preferably greater than 2. Here, the color impression of the layer system is C_{layer}=(L*ₗ, a*ₗ, b*ₗ) and the color impression of the substrate is C=(L*, a*, b*).

The method may also comprise pretreatment and/or cleaning steps both for the substrate 12 and for the substrate with the metal layer 14. Such a cleaning and/or pretreatment method may be a plasma pretreatment. In this case, the substrate 12 is cleaned by a plasma and activated for better adhesion of the subsequent metal layer 14.

Exemplary embodiment of a method for producing a layer system:

A method for producing a metal layer 14 comprising tin and a further layer 24 comprising titanium nitride (Sn/TiₓN_{y} with 1<x<1.5 and 0.5<y<2) will be described below. The substrate is introduced into a vacuum chamber of a coating apparatus, for example an AluMet 900H of the Applicant. Tin pellets are fitted onto molybdenum filaments. The substrate is arranged on a sample holder, which is fitted on a coating carriage. The coating carriage is moved into the vacuum chamber. The vacuum chamber is evacuated to 5×10⁻³ Pa.

The sample holder rotates, a current for evaporating the tin pellets onto the substrate surfaces being passed through the heating filaments. The substrate surfaces are arranged opposite the heating filaments with the tin pellets. The evaporating tin particles condense on the substrate surface to form a tin layer. The thickness of the tin layer is typically 35 nm. The applied layers are metallically lustrous with an optical density of about 1.5. This corresponds to about 3% residual transmission. The metal layer 14 furthermore has a reflection of from 60% to 70% in the visible wavelength range, and a sheet resistance of more than 10 Mohm. Once the coating process is completed, air is let into the vacuum chamber and the substrate with the metal layer 14 is removed.

In the next method step, the substrate 12 with the metal layer 14 is introduced into a coating apparatus, typically a Topaz reactive sputtering apparatus of the Applicant. The initial process pressure in the vacuum chamber is 2×10⁻³ Pa. With a sputtering atmosphere of 110 sccm argon and 200 sccm nitrogen, a titanium target is sputtered with a power of 15 kW. A 40 kHz plasma of 500 W is simultaneously ignited in order to assist the nitriding reaction.

TABLE 1
Colors and electrical resistances of sputtered TiₓN_{y} layers

| 0.44 nm/s | | | | | |
|---|---|---|---|---|---|
| Sputtering | Thick- | | | | Resistance |
| time [s] | ness [nm] | L* | a* | b* | R, Mohm |
| 0 | 0 | 86.37 | −1.36 | 5.5 | >20 |
| 50 | 22 | 79.3 | −0.82 | 26.61 | >20 |
| 75 | 33 | 67.22 | 6.11 | 53.2 | >20 |
| 100 | 44 | 59.33 | 11.78 | 64.77 | >20 |
| 120 | 52 | 37.89 | 29.62 | 34.3 | >20 |
| 125 | 55 | 33.03 | 27.7 | −3.53 | >20 |
| 150 | 66 | 28.4 | 8.05 | −31.21 | >20 |
| 180 | 79.2 | 31.55 | −12.45 | −33.89 | 10 . . . >20 |
| 200 | 88 | 48.66 | −19.45 | −18.42 | >20 |
| 225 | 99 | 57.8 | −18.38 | 1.51 | >17 |
| 250 | 110 | 60.54 | −15.2 | 14.08 | >20 |
| 180 | 79.2 | 57.11 | −1.3 | 14.45 | 0.03 |

Table 1 shows the color coordinates L*, a* and b* of TiₓN_{y} layers on a nonconductive tin layer on a glass substrate as a function of the sputtering time in seconds, and a resulting thickness of the layer in nm. The color coordinate L* denotes the lightness, a* the red-green shift and b* the yellow-blue shift.

The respectively measured sheet resistance R is given in Mohm in the right-hand column. The TiₓN_{y} layers with a thickness of between 20 and 110 nm on the nonconductive metal layer have resistances >10 Mohm.

The last row of Table 1 shows for comparison the values of a TiₓN_{y} layer with a thickness of about 80 nm, which was applied onto a glass substrate with the same process parameters and a process time of 180 s, a sheet resistance of 0.03 Mohm having been measured.

In the measurements, the color impression L*a*b* was determined with a CIE standard illuminant, preferably D65, and a 2° or 10° observer. For measurements of the spectral reflectance, a color measuring device from the company X-Rite Inc. (4300 44th Street SE, Grand Rapids, Mich., 49512 USA) model SP60 may for example be used.

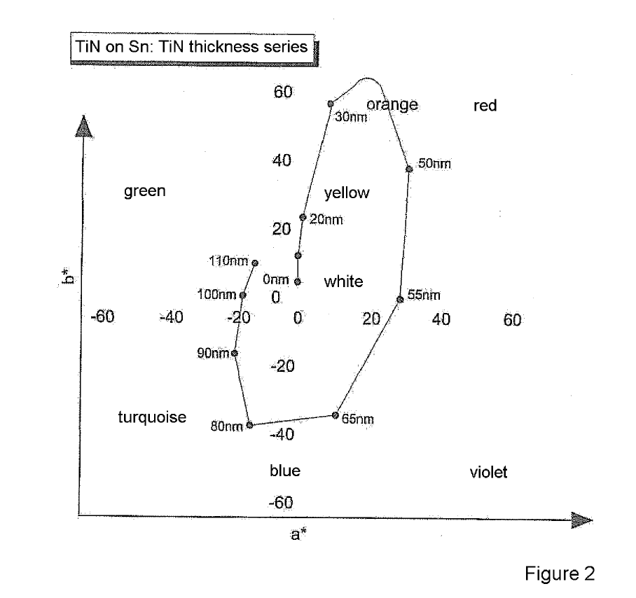

FIG. 2 shows by way of example the colors dependent on the thickness of the TiₓN_{y} layer in a projection of the L*a*b* color space onto the a*-b* plane as a thickness series on a tin layer. a* is plotted on the x axis and b* on the y axis. The layer thickness is respectively indicated at the measurement points. It can be seen that different layer thicknesses of from 20 nm to 110 nm are assigned different colors.

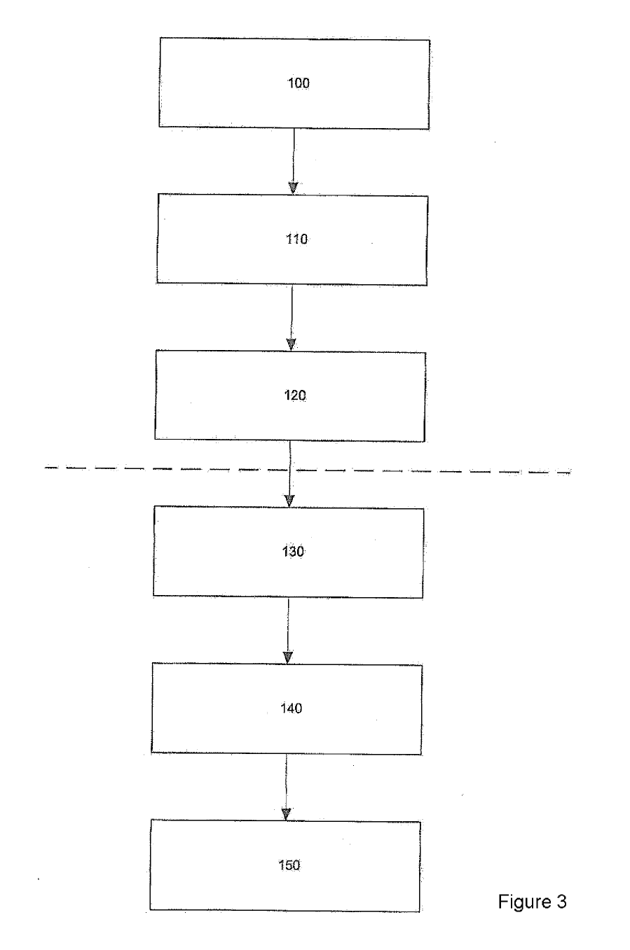

FIG. 3 shows a flow chart of a method according to the invention for producing an electrically nonconductive layer system.

In method step 100, the substrate 12 is introduced into the vacuum chamber and the vacuum chamber is pumped out, typically to a pressure of 5×10⁻³ Pa.

In method step 110, the substrate is coated and a discontinuous metal layer 14 is deposited on the substrate.

In method step 120, air is let into the vacuum chamber and the substrate 12 with the metal layer 14 is removed therefrom. In method step 130, the substrate 12 is introduced into a second vacuum chamber and the latter is evacuated, typically to a pressure of 2×10⁻³ Pa.

In method step 140, a coating process for applying a further layer 24 is carried out.

Thicknesses of the further layer 24 typically achieved in tests by the Applicant are from 20 nm to 300 nm for TiₓN_{y} layers. Once the desired thickness of the further layer 24 has been reached, the substrate 12 with the metal layer 14 and the further layer 24 is removed from the apparatus in method step 150.

Even though the method has been explained for two different vacuum apparatuses, the method may also be carried out without breaking the vacuum in vacuum apparatuses suitable for this, in which case intermediate removal and introduction of the substrate can be obviated.

The method may comprise further pretreatment steps, cleaning steps and/or method steps not explicitly mentioned here.

1. Method for producing a layer system on a dielectric substrate in which:
a metal layer is applied onto the substrate by a coating step (110) and
a further layer with a predetermined layer thickness is subsequently applied by a further coating step (140),
the metal layer having a sheet resistance >10 Mohm and an average reflectance >50%,
wherein the further layer, if it was applied onto the substrate with the same layer thickness by the further coating step (140), would have a sheet resistance <1 Mohm, and the layer system comprising the metal layer and the further layer has a sheet resistance >10 Mohm.

2. Method according to claim 1, wherein the metal layer is applied with a layer thickness >30 nm and <100 nm and/or the further layer is applied with a layer thickness >20 nm and <300 nm.

3. Method according to claim 1, wherein the metal layer is produced from an element comprising tin, indium, lead, bismuth, aluminum, cerium, chromium, gallium or iridium.

4. Method according to claim 1, wherein the metal layer is produced from an alloy of at least two elements comprising tin, indium, lead, bismuth, aluminum, cerium, chromium, gallium or iridium.

5. Method according to claim 1, wherein the metal layer is applied by a vacuum method comprising a PVD or PECVD method and/or the further layer is applied by a vacuum method comprising a reactive PVD or PECVD method.

6. Method according to claim 5, wherein the further layer is applied by reactive sputtering with an element comprising titanium, zirconium, cerium, aluminum, iridium, or chromium, with a reactive gas which comprises an element comprising nitrogen, carbon, oxygen, boron, silicon, niobium, or tantalum.

7. Method according to claim 1, wherein the average reflectance of the layer system in the frequency range of between 400 MHz and 5 GHz, differs by <25% from a corresponding average reflectance of the substrate without the layer system.

8. Method according to claim 1, wherein there is a color distance ΔE*=[(L*ₗ−L*)²+(a*ₗ−a*)²+(b*ₗ−b*)²]^{1/2}>2.0 between the color impression of the substrate with the layer system applied and the color impression of the substrate without the layer system, the color impression of the layer system being C_{layer}=(L*ₗ, a*ₗ, b*ₗ) and the color impression of the substrate being C=(L*, a*, b*).

9. Layer system on a dielectric substrate in which a metal layer is applied onto the substrate by a coating step and a further layer with a predetermined layer thickness is subsequently applied by a further coating step, the metal layer having a sheet resistance >10 Mohm and an average reflectance >50%, wherein the further layer, if it had been applied onto the substrate with the same layer thickness by the further coating step (140), would have a sheet resistance <1 Mohm, and the layer system comprising the metal layer and the further layer has a sheet resistance >10 Mohm.

10. Layer system according to claim 9, wherein the metal layer has a layer thickness >30 nm and <100 nm and/or the further layer has a layer thickness >20 nm and <300 nm.

11. Layer system according to claim 9, wherein the metal layer comprises at least one of tin, indium, lead, bismuth, gallium, aluminum, cerium, chromium and iridium.

12. Layer system according to claim 9, wherein the metal layer comprises an alloy of at least two elements of comprising tin, indium, lead, bismuth, gallium, aluminum, cerium, chromium or iridium.

13. Layer system according to claim 9, wherein the metal layer is applied by a vacuum method comprising a PVD or PECVD method and/or the further layer is applied by a vacuum method comprising a reactive PVD or PECVD method.

14. Layer system according to claim 13, wherein the further layer is applied by reactive sputtering of an element comprising titanium, zirconium, cerium, aluminum, iridium, or chromium, with a reactive gas which comprises an element comprising nitrogen, carbon, oxygen, boron, silicon, niobium, or tantalum.

15. Layer system according to claim 9, wherein the average reflectance of the layer system, in the frequency range of between 400 MHz and 5 GHz, differs by <25% from a corresponding average reflectance of the substrate without the layer system.

16. Layer system according to claim 9, wherein there is a color distance ΔE*=[(L*ₗ−L*)²+(a*ₗ−a*)²+(b*ₗ−b*)²]^{1/2}>2.0 between the color impression of the substrate with the layer system applied and the color impression of the substrate without the layer system, the color impression of the layer system being C_{layer}=(L*ₗ, a*ₗ, b*ₗ) and the color impression of the substrate being C=(L*, a*, b*).

17. Housing comprising a housing body, which is used as a dielectric substrate, and a layer system according to claim 9.
